(19) United States
(12) Patent Application Publication
(10) Pub. No.: US 2024/0414952 A1
(43) Pub. Date: Dec. 12, 2024

(54) DISPLAY PANEL AND METHOD FOR MANUFACTURING DISPLAY PANEL

(71) Applicant: Hefei Visionox Technology Co., Ltd., Hefei (CN)

(72) Inventors: Zengqiang XIA, Hefei (CN); Yuan YAO, Hefei (CN); Zhengkui DONG, Hefei (CN); Yiming XIAO, Hefei (CN)

(73) Assignee: Hefei Visionox Technology Co., Ltd., Hefei (CN)

(21) Appl. No.: 18/644,634

(22) Filed: Apr. 24, 2024

Related U.S. Application Data
(63) Continuation of application No. PCT/CN2023/130364, filed on Nov. 8, 2023.

(30) Foreign Application Priority Data
Jun. 9, 2023 (CN) 202310692671.8

(51) Int. Cl. H10K 59/122; H10K 59/12; H10K 59/131

(52) U.S. Cl. CPC H10K 59/122; H10K 59/1201; H10K 59/131

(57) ABSTRACT

A display panel and a method for manufacturing a display panel. The display panel includes: a substrate; an isolation structure arranged on one side of the substrate, a first opening being enclosed by the isolation structure; a light-emitting functional layer, at least part of the light-emitting functional layer being arranged in the first opening; and a first electrode arranged on a side of the light-emitting functional layer facing away from the substrate, the first electrode being connected to the isolation structure. An orthographic projection of the first opening on the substrate has a first outer edge facing the light-emitting functional layer, the first outer edge including a first section, and an angle between an extension line of the first section and the first direction is greater than or equal to 0° and less than or equal to 26°.

### CROSS-REFERENCE TO RELATED APPLICATIONS

This application is a continuation of International Application No. PCT/CN2023/130364, filed on Nov. 8, 2023, which claims priority to Chinese Patent Application No. 202310692671.8, entitled DISPLAY PANEL AND METHOD FOR MANUFACTURING DISPLAY PANEL”, filed on Jun. 9, 2023, both of which are hereby incorporated by reference in their entireties.

### TECHNICAL FIELD

The present application relates to the technical field of electronic products, and in particular, to a display panel and a method for manufacturing a display panel.

### BACKGROUND

With the development of science and technology, digital display apparatuses such as smart phones and tablet computers have been widely used, and display panel is an indispensable interpersonal communication interface in these display apparatuses. A display panel such as an organic light emitting diode (OLED) has advantages of self-illumination, energy saving, consumption reduction, bendability, and good flexibility. Moreover, the display apparatus for display does not require a backlight and is characterized by fast response speed and good display effect, which has attracted attention of users and is widely used in terminal products such as smart phones and tablet computers.

However, the display effect of the display panel cannot meet requirements.

### SUMMARY

Embodiments of the present application provide a display panel and a method for manufacturing a display panel, which increases an overlapping height of a first electrode with an isolation structure, thereby increasing overlapping area between the first electrode and the isolation structure, improving overlapping effect between the first electrode and the isolation structure, and improving display effect of the display panel.

In a first aspect, an embodiment of the present application provides a display panel, the display panel having a first sub-edge extending along a first direction, the display panel including: a substrate; an isolation structure arranged on a side of the substrate, a first opening being enclosed by the isolation structure; a light-emitting functional layer, at least part of the light-emitting functional layer being arranged in the first opening; and a first electrode arranged on a side of the light-emitting functional layer facing away from the substrate, the first electrode being connected to the isolation structure; wherein an orthographic projection of the first opening on the substrate has a first outer edge facing the light-emitting functional layer, the first outer edge including a first section, and an angle between an extension line of the first section and the first direction is greater than or equal to 0° and less than or equal to 26°.

In a second aspect, an embodiment of the present application provides a display panel, including: a substrate; a data line and a scanning line that are arranged on a side of the substrate; an isolation structure arranged on a side of the substrate, a first opening being enclosed by the isolation structure; a light-emitting functional layer, at least part of the light-emitting functional layer being arranged in the first opening; and a first electrode arranged on a side of the light-emitting functional layer facing away from the substrate, the first electrode being in contact with the isolation structure; wherein an orthographic projection of the first opening on the substrate has a first outer edge facing the light-emitting functional layer, the first outer edge including a first section, and an angle between an extension line of the first section and a first direction is greater than or equal to 0° and less than or equal to 26°, wherein the first direction is an extension direction of any one of the data line and the scanning line.

In a third aspect, an embodiment of the present application provides a display panel, including: a substrate; an isolation structure arranged on a side of the substrate, a first opening being enclosed by the isolation structure; a pixel defining layer arranged on a side of the substrate, the pixel defining layer including a defining structure and a plurality of second openings defined by the defining structure; and a light-emitting functional layer, at least part of the light-emitting functional layer being arranged in the second openings; wherein an orthographic projection of the first opening on the substrate has a first outer edge facing the second opening, an orthographic projection of the second opening on the substrate has a second outer edge, and the first outer edge is not parallel to the second outer edge adjacent thereto.

In a fourth aspect, an embodiment of the present application provides a method for manufacturing a display panel, including the following steps: providing a substrate; forming an isolation structure on a side of the substrate, a first opening being enclosed by the isolation structure; forming a light-emitting functional layer, at least part of the light-emitting functional layer being arranged in the first opening; and forming a first electrode on a side of the light-emitting functional layer facing away from the substrate, the first electrode being connected to the isolation structure, wherein an orthographic projection of the first opening on the substrate has a first outer edge facing the light-emitting functional layer, the first outer edge including a first section, and an angle between an extension line of the first section and an arrangement direction of nozzle portions on a linear evaporation source configured to evaporate the first electrode is greater than or equal to 0° and less than or equal to 26°.

Compared with the prior art, the display panel provided in the embodiments of the present invention includes a substrate, an isolation structure, a light-emitting functional layer, and a first electrode. A first opening is enclosed by the isolation structure to define a setting range of the light-emitting functional layer. An orthographic projection of the first opening on the substrate has a first outer edge facing the light-emitting functional layer. The display panel has a first sub-edge extending along a first direction. That is, the first sub-edge is a straight edge of the display panel. The inventor has found through research that when an angle between an extension line of the first section and the first direction is greater than or equal to 0° and less than or equal to 26° and during the manufacturing for the first electrode, overlapping height of the first electrode with the isolation structure can be effectively increased, thereby increasing overlapping area between the first electrode and the isolation structure, improving overlapping effect between the first electrode and the isolation structure, and improving display effect of the display panel.

### BRIEF DESCRIPTION OF THE DRAWINGS

FIG. 1 is a schematic structural diagram of a display panel according to an embodiment of the present invention;

FIG. 2 is a schematic diagram of an enlarged structure of a region Q in FIG. 1 according to an embodiment of the present invention;

FIG. 3 is a schematic diagram of a sectional structure at A-A in FIG. 2;

FIG. 4 is a schematic diagram of an enlarged structure of the region Q in FIG. 1 according to another embodiment of the present invention;

FIG. 5 is a schematic structural diagram of a linear evaporation source according to an embodiment of the present invention;

FIG. 6 is a schematic diagram of relative positions of a linear evaporation source and a first opening in the prior art;

FIG. 7 is a schematic diagram of a sectional structure at B-B in FIG. 6;

FIG. 8 is a schematic diagram of relative positions of a linear evaporation source and a first opening according to an embodiment of the present invention;

FIG. 9 is a schematic diagram of a sectional structure at C-C in FIG. 8;

FIG. 10 is a flowchart of a method for manufacturing a display panel according to an embodiment of the present invention;

FIG. 11 is a schematic sectional view of a structure obtained in step S110 in the method for manufacturing the display panel according to an embodiment of the present invention;

FIG. 12 is a schematic sectional view of a structure obtained in step S120 in the method for manufacturing the display panel according to an embodiment of the present invention; and

FIG. 13 is a schematic sectional view of a structure obtained in step S130 in the method for manufacturing the display panel according to an embodiment of the present invention.

### DETAILED DESCRIPTION

Features and exemplary embodiments in various aspects of the present application will be described in detail below. To make the objectives, technical solutions, and advantages of the present application clearer, the present application will be further described in detail below with reference to the accompanying drawings and specific embodiments. It should be understood that the specific embodiments described herein are merely configured to illustrate the present application, rather than to limit the present application. For those skilled in the art, the present application can be implemented without some of these specific details. The following description of the embodiments is merely to provide a better understanding of the present application by illustrating the examples of the present application.

It will be apparent to those skilled in the art that various modifications and variations can be made in the present application without departing from the spirit or scope of the present application. Thus, the present application is intended to cover modifications and variations of the present application which fall within the scope of the appended claims (claimed technical solution) and their equivalents. It is to be noted that implementations provided in the embodiments of the present application may be combined with each other without contradiction.

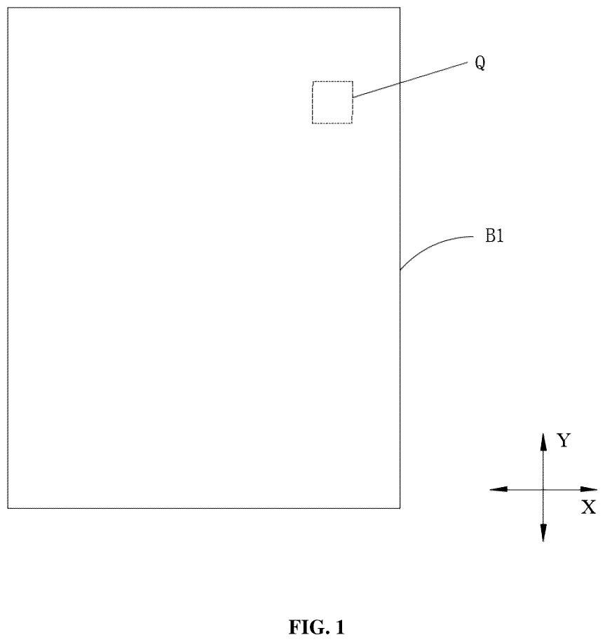

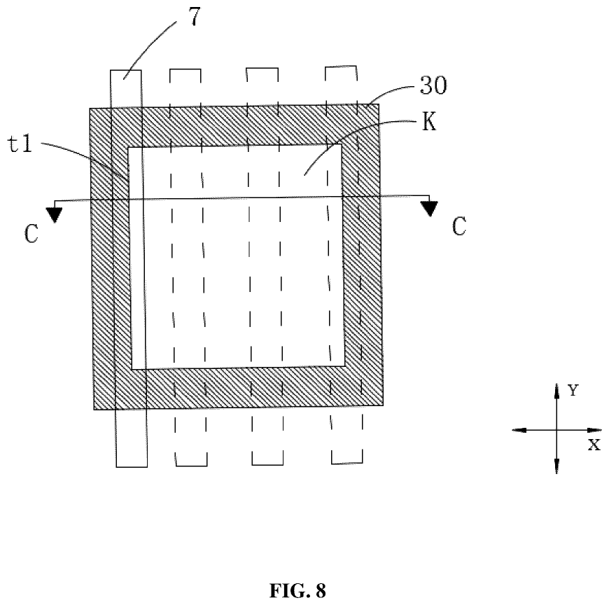

The embodiments of the present application provide a display panel and a method for manufacturing a display panel. Various embodiments of the display panel will be described below with reference to FIG. 1 to FIG. 13.

Referring to FIG. 1 to FIG. 3, an embodiment of the present application provides a display panel. The display panel has a first sub-edge B1 extending along a first direction Y. The display panel includes: a substrate 10; an isolation structure 30 arranged on one side of the substrate 10, a first opening K is enclosed by the isolation structure 30; a light-emitting functional layer 40, at least part of the light-emitting functional layer 40 being arranged in the first opening K; and a first electrode 50 arranged on a side of the light-emitting functional layer 40 facing away from the substrate 10, the first electrode 50 being connected to the isolation structure 30. An orthographic projection of the first opening K on the substrate 10 has a first outer edge d1 facing the light-emitting functional layer 40, the first outer edge d1 includes a first section t1, and an angle between an extension line of the first section t1 and the first direction Y is greater than or equal to 0° and less than or equal to 26°.

The display panel provided in this embodiment of the present invention includes the substrate 10, the isolation structure 30, the light-emitting functional layer 40, and the first electrode 50. The first opening K is enclosed by the isolation structure 30 to define a setting range of the light-emitting functional layer 40. The orthographic projection of the first opening K on the substrate 10 has the first outer edge d1 facing the light-emitting functional layer 40. The display panel has the first sub-edge B1 extending along the first direction Y. That is, the first sub-edge B1 is a straight edge of the display panel. Since an arrangement direction of each nozzle portion 72 on a linear evaporation source 7 configured to evaporate the first electrode 50 is generally parallel to the first direction Y, the inventor has found through research that when the angle between the extension line of the first section t1 and the first direction Y is greater than or equal to 0° and less than or equal to 26° during the manufacturing for the first electrode 50, an overlapping height of the first electrode 50 with the isolation structure 30 can be effectively increased, thereby increasing overlapping area between the first electrode 50 and the isolation structure 30, improving overlapping effect between the first electrode 50 and the isolation structure 30, and improving display effect of the display panel.

The inventor has found through research that the angle between the extension line of the first section t1 and the first direction Y may affect a relative position between a maximum evaporation path formed by an evaporation material ejected from each nozzle portion 72 on the linear evaporation source 7 configured to evaporate the first electrode 50 and the isolation structure 30, thereby affecting overlapping position of the formed first electrode 50 on the isolation structure 30. In this embodiment of the present application, the angle between the extension line of the first section t1 and the first direction Y is limited to being greater than or equal to 0° and less than or equal to 26° to increase the overlapping height of the first electrode 50 on the isolation structure 30, so that the overlapping effect between the first electrode 50 and the isolation structure 30 meets the requirement, improving the display effect of the display panel.

The first direction Y is parallel to the arrangement direction of each nozzle portion 72 on the linear evaporation source 7 configured to evaporate the first electrode 50.

The linear evaporation source 7 is generally a strip in shape. The linear evaporation source 7 is provided with a plurality of nozzle portions 72, and the nozzle portions 72 are arranged along a straight line. An extension direction of the straight line is the arrangement direction of each nozzle portion 72. For example, a body portion 71 and nozzle portions 72 arranged on the body portion 71 along an extension direction of the body portion 71 are included. A plurality of nozzle portions 72 are sequentially arranged on the body portion 71. The arrangement direction of each nozzle portion 72 may affect an evaporation range. The first direction Y is parallel to the arrangement direction of each nozzle portion 72 on the linear evaporation source 7 configured to evaporate the first electrode 50. Correspondingly, an angle between the extension line of the first section t1 and the arrangement direction of each nozzle portion 72 on the linear evaporation source 7 configured to evaporate the first electrode 50 is greater than or equal to 0° and less than or equal to 26°, so as to define a relative position between the maximum evaporation path formed by the evaporation material ejected from each nozzle portion 72 and the isolation structure 30 and increase the overlapping height of the first electrode 50 on the isolation structure 30, so that the of overlapping effect between the first electrode 50 and the isolation structure 30 meets the requirement, improving the display effect of the display panel.

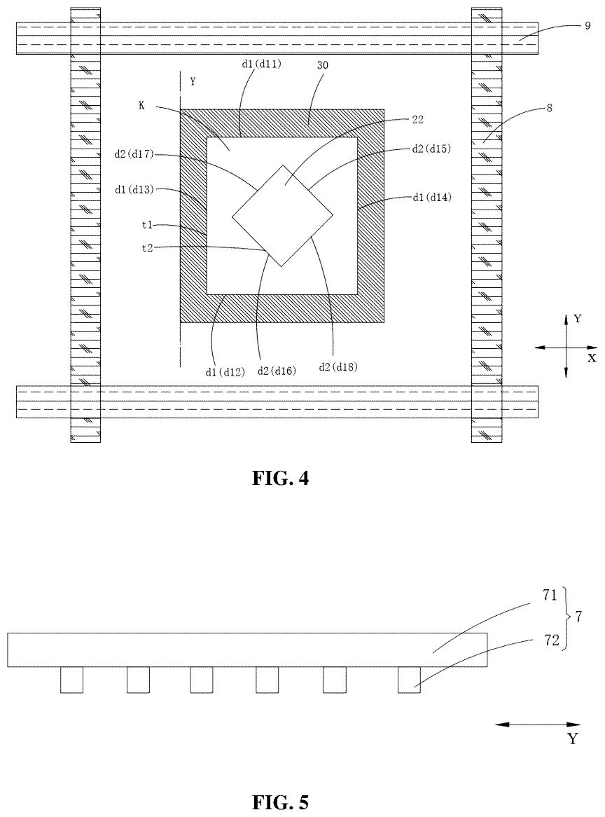

Optionally, as shown in FIG. 4 and FIG. 5, when the angle between the extension line of the first section t1 and the arrangement direction of each nozzle portion 72 on the linear evaporation source 7 configured to evaporate the first electrode 50 is equal to 0°, that is, the extension line of the first section t1 is parallel to the arrangement direction of each nozzle portion 72 on the linear evaporation source 7 configured to evaporate the first electrode 50, the overlapping height of the first electrode 50 on the isolation structure 30 is higher, improving the display effect of the display panel.

Optionally, the first direction Y is perpendicular to a moving direction of the linear evaporation source 7 configured to evaporate the first electrode 50. That is, the arrangement direction of each nozzle portion 72 on the linear evaporation source 7 configured to evaporate the first electrode 50 is perpendicular to the moving direction of the linear evaporation source 7 configured to evaporate the first electrode 50. The inventor has found through research that the moving direction of the linear evaporation source 7 configured to evaporate the first electrode 50 may also affect the overlapping height of the first electrode 50 on the isolation structure 30, when the arrangement direction of each nozzle portion 72 on the linear evaporation source 7 configured to evaporate the first electrode 50 is perpendicular to the moving direction of the linear evaporation source 7 configured to evaporate the first electrode 50 and the angle between the extension line of the first section t1 and the arrangement direction of each nozzle portion 72 on the linear evaporation source 7 configured to evaporate the first electrode 50 is greater than or equal to 0° and less than or equal to 26°, the overlapping height of the first electrode 50 on the isolation structure 30 meets the requirement, which can realize stable overlapping between the first electrode 50 and the isolation structure 30, improving the display effect of the display panel.

Optionally, the display panel includes a data line 8 and a scanning line 9, one of the data line 8 and the scanning line 9 extends along the first direction Y, and the other extends along a second direction X, and the first direction Y intersects the second direction X. The data line 8 may extend along the first direction Y or the scanning line 9 may extend along the first direction Y, which is not specially limited and may be set according to an actual requirement.

The display panel is generally a rectangle in shape. The first sub-edge B1 may be a short edge or a long edge of the display panel, which is not specially limited.

The orthographic projection of the first opening K on the substrate 10 has the first outer edge d1 facing the light-emitting functional layer 40. The first section t1 of the first outer edge d1 may be understood as an edge corresponding to a side of the isolation structure 30 used to be overlapped with the first electrode 50. Since an angle between the extension line of the first section t1 of the first outer edge d1 and the first direction Y is required to be greater than or equal to 0° and less than or equal to 26°, the first section t1 is a straight section, and the orthographic projection of the corresponding first opening K on the substrate 10 is required to be a pattern including at least one straight edge, such as a rectangle or a trapezoid.

Optionally, a plurality of first openings K are distributed at intervals, and each first opening K is provided with the light-emitting functional layer 40.

Optionally, the display panel further includes a second electrode 60, and the second electrode 60 is located on a side of the light-emitting functional layer 40 facing the substrate 10.

Optionally, a plurality of first electrodes 50 are provided, and each first electrode 50 is located on a side of the light-emitting functional layer 40 facing away from the substrate 10.

The second electrode 60 and the first electrode 50 interact with each other to drive the light-emitting functional layer 40 to emit light. One of the first electrode 50 and the second electrode 60 is an anode, and the other is a cathode. In this embodiment of the present application, for example, the second electrode 60 is an anode, and the first electrode 50 is a cathode.

Optionally, the display panel may include a substrate 10 and a circuit layer. The circuit layer may include a drive circuit. For example, the circuit layer may include a first conductive layer, a second conductive layer, and a third conductive layer arranged on one side of the substrate 10 in stack. Insulating layers are arranged between adjacent conductive film layers. Exemplarily, a pixel circuit arranged on the circuit layer includes a transistor and a storage capacitor. The transistor includes a semiconductor, a gate, a source, and a drain. The storage capacitor includes a first plate and a second plate. As an example, the gate and the first plate may be located on the first conductive layer, the second plate may be located on the second conductive layer, and the source and the drain may be located on the third conductive layer.

Optionally, the light-emitting functional layer 40 includes one or more of an electron injection layer, an electron transport layer, a light-emitting material layer, a hole blocking layer, an electron blocking layer, a hole transport layer, and a hole injection layer. A selection may be specifically made according to a specific type of the light-emitting functional layer 40, which is not specially limited. The electron injection layer, the electron transport layer, and the hole blocking layer may be arranged between the first electrode 50 and the light-emitting material layer. The electron blocking layer, the hole transport layer, and the hole injection layer may be arranged between the second electrode 60 and the light-emitting material layer.

The first electrode 50 may be made of one of metal materials such as silver (Ag), aluminum (Al), lithium (Li), magnesium (Mg), ytterbium (Yb), calcium (Ca), and indium (In), or made of an alloy of the above metal materials, such as a magnesium-silver alloy (Mg/Ag) or a lithium aluminum alloy (Li/Al), which is not limited in this embodiment.

The second electrode 60 is generally made of a material with a high work function in order to improve hole injection efficiency, which may be gold (Au), platinum (Pt), titanium (Ti), Ag, indium tin oxide (ITO), zinc tin oxide (IZO), or a transparent conductive polymer (such as polyaniline). For example, the second electrode 60 may be made of an ITO-Ag-ITO composite material, which is not specially limited.

Optionally, a planarization layer is also included between the substrate 10 and the pixel defining layer 20. The planarization layer may be made of hexamethyldimethylsilyl ether, epoxy resin, or polyimide, or made of other materials, which is not limited in this embodiment.

In some optional embodiments, the first outer edge d1 is a polygon in shape and includes a plurality of sides with different lengths, and the first section t1 is the longest side in the plurality of sides with different lengths.

Since the first section t1 is an edge corresponding to the side of the isolation structure 30 used to be overlapped with the first electrode 50, a side of the isolation structure 30 corresponding to the first section t1 is used to be overlapped with the first electrode 50. The first section t1 is the longest side in the plurality of sides with different lengths, which increases overlapping length between the first electrode 50 and one side of the corresponding isolation structure 30, thereby increasing overlapping area between the first electrode 50 and one side of the corresponding isolation structure 30.

At the same time, since the first section t1 is the longest side in the plurality of sides with different lengths, when the angle between the extension line of the first section t1 and the first direction Y is greater than or equal to 0° and less than or equal to 26°, the overlapping height of the formed first electrode 50 on the isolation structure 30 is increased, so that the overlapping effect between the first electrode 50 and the isolation structure 30 is more significantly improved, effectively improving the display effect of the display panel.

According to a different shape of the first outer edge d1, the first section t1 is a different side. For example, when the first sub-edge B1 is an oblong in shape, the first section t1 may include two long sides of the oblong.

Referring to FIG. 3, in some optional embodiments, the display panel further includes a pixel defining layer 20 arranged between the substrate 10 and the isolation structure 30, the pixel defining layer 20 includes a defining structure 21 and a second opening 22 defined by the defining structure 21, and an orthographic projection of the second opening 22 on the substrate 10 is located within a range of the orthographic projection of the first opening K on the substrate 10.

In this embodiment, area of the first opening K is greater than or equal to that of the second opening 22, which can reduce an impact of the isolation structure 30 on a light emission viewing angle of the light-emitting functional layer 40.

Optionally, the orthographic projection of the second opening 22 on the substrate 10 has a second outer edged d2, and the first outer edge d1 is not parallel to the second outer edge d2 adjacent thereto.

In the prior art, the second opening 22 and the first opening K generally adopt similar patterns, that is, patterns of orthographic projections of the second opening 22 and the first opening K on the substrate 10 have a same shape, but areas of the orthographic projections of the second opening 22 and the first opening K on the substrate 10 are different. Moreover, opposite edges of the second opening 22 and the first opening K are parallel to each other, that is, there is a fixed matching relationship between the second opening 22 and the first opening K. On the one hand, it is not conducive to targeted adjustment of the light emission effect when the light-emitting functional layer 40 emits light from the first opening K.

On the other hand, in order to ensure image quality, the existing second opening 22 generally has a shape such as a diamond or a rectangle, and an edge thereof is at an angle of 45° or other angles with the first sub-edge B1 of the display panel, which cannot be parallel or perpendicular. As a result, when the first electrode 50 is formed by evaporation, the angle between the extension line of the first section t1 and the arrangement direction of each nozzle portion 72 on the linear evaporation source 7 configured to evaporate the first electrode 50 cannot satisfy the angle relationship of being greater than or equal to 0° and less than or equal to 26°, which affects a climbing effect of the first electrode 50.

In order to solve the above problem, in this embodiment of the present invention, the matching relationship between the second opening 22 and the first opening K is eliminated, so that the first outer edge d1 and the adjacent second outer edge d2 are not parallel, which can adjust, in a targeted manner, the light emission effect when the light-emitting functional layer 40 emits light from the first opening K, and can also improve the overlapping effect between the first electrode 50 and the isolation structure 30 by adjusting the angle between the extension line of the first section t1 and the arrangement direction of each nozzle portion 72 on the linear evaporation source 7 configured to evaporate the first electrode 50.

Optionally, the second outer edge d2 is a polygon in shape, and angles between extension lines of sides of the polygon and the first direction Y are all greater than 26°. Correspondingly, in the prior art, angles between sides of the first outer edge d1 and the first direction Y are all greater than 26°, and the overlapping effect between the first electrode 50 and the isolation structure 30 cannot meet the requirement. Therefore, there is a need to correspondingly adjust the shape of the first outer edge d1 in this embodiment so that the angle between the extension line of the first section t1 and the first direction Y is limited to being greater than or equal to 0° and less than or equal to 26° to increase the overlapping height of the first electrode 50 on the isolation structure 30, and the overlapping effect between the first electrode 50 and the isolation structure 30 meets the requirement, improving the display effect of the display panel.

Optionally, the second outer edge d2 includes a second section t2, and an extension line of the second section t2 is not parallel to the arrangement direction of each nozzle portion 72 on the linear evaporation source 7 configured to evaporate the first electrode 50.

In this embodiment, since the arrangement direction of each nozzle portion 72 on the linear evaporation source 7 configured to evaporate the first electrode 50 is generally parallel to the first direction Y, the extension line of the second section t2 is not parallel to the arrangement direction of each nozzle portion 72 on the linear evaporation source 7 configured to evaporate the first electrode 50, that is, the extension line of the second section t2 is not parallel to the first direction Y, and there is a certain angle between them.

Optionally, the second outer edge d2 includes a second section t2, and an angle between an extension line of the second section t2 and the first direction Y is 45°, that is, an angle between the extension line of the second section t2 and an extension line of the first sub-edge B1 of the display panel is 45°, to ensure the light emission effect of the display panel.

Referring to FIG. 4, in some optional embodiments, the orthographic projection of the second opening 22 on the substrate 10 has at least one axis of symmetry, and the orthographic projection of the first opening K on the substrate 10 is symmetrically arranged with respect to the at least one axis of symmetry.

By arranging the orthographic projection of the first opening K on the substrate 10 symmetrically with respect to the at least one axis of symmetry, optical symmetry effect of the display panel can be improved. For example, when the orthographic projections of the second opening 22 and the first opening K on the substrate 10 are both a square in shape, the orthographic projection of the second opening 22 on the substrate 10 has four axes of symmetry, and the orthographic projection of the first opening K on the substrate 10 may be rotated by 45° relative to the orthographic projection of the second opening 22 on the substrate 10, so that the orthographic projection of the first opening K on the substrate 10 can be symmetrical about the four axes of symmetry of the second opening 22 to exhibit excellent optical symmetry effect.

In some optional embodiments, the isolation structure 30 includes a first part 31 and a second part 32 sequentially arranged along a direction away from the substrate 10, and an orthographic projection of the first part 31 on the substrate 10 is located within an orthographic projection of the second part 32 on the substrate 10.

In this embodiment, since the orthographic projection of the first part 31 on the substrate 10 is located within the orthographic projection of the second part 32 on the substrate 10, a size of the first part 31 is smaller than or equal to that of the second part 32 so that the isolation structure 30 separates the light-emitting functional layer 40 from the first electrode 50.

Optionally, the second part 32 extends outwards by a predetermined distance relative to the first part 31, that is, an area of a side surface of the first part 31 facing away from the substrate 10 on the substrate 10 is smaller than that of a side surface of the second part 32 facing the substrate 10 on the substrate 10, so as to define patterns of the light-emitting functional layer 40 and the first electrode 50.

Optionally, the first part 31 includes a first side surface C1 facing the first opening K and overlapping with the first electrode 50, the second part 32 includes a second side surface C2 facing the first opening K, and an edge of the orthographic projection of the first part 31 on the substrate 10 is parallel to an edge of the orthographic projection of the second part 32 on the substrate 10, to ensure that the first electrode 50 can pass through the second part 32 smoothly, enter the first opening K, and overlap the first part 31, and to ensure consistency of the influence of the angle relationship between the arrangement direction of each nozzle portion 72 on the linear evaporation source 7 configured to evaporate the first electrode 50 and the first section t1 of the first outer edge d1 on the first part 31 and the second part 32.

Optionally, the edge of the orthographic projection of the first part 31 on the substrate 10 coincides with the first outer edge d1; or the edge of the orthographic projection of the second part 32 on the substrate 10 coincides with the first outer edge d1.

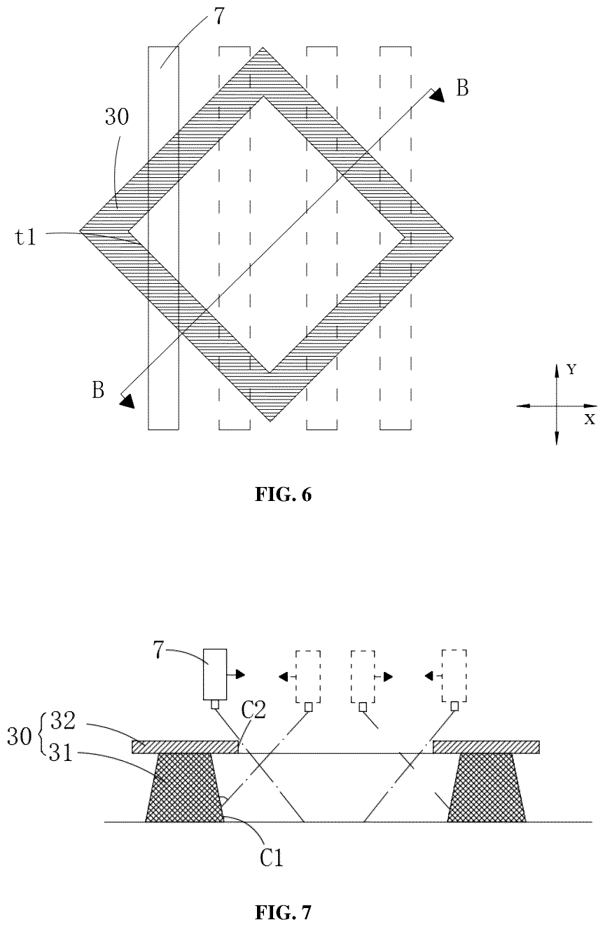

Considering that the first electrode 50 is required to overlap with the first side surface C1 of the first part 31, the edge of the orthographic projection of the first part 31 on the substrate 10 may coincide with the first outer edge d1. Correspondingly, the angle between the extension line of the first section t1 and the first direction Y may correspondingly affect an angle between the maximum evaporation path formed by the evaporation material ejected from each nozzle portion 72 on a section perpendicular to the extension line of the first section t1 and the first side surface C1. As shown in FIG. 6 to FIG. 9, a section of the isolation structure 30 formed along B-B is perpendicular to the extension line of the first section t1. If the angle between the extension line of the first section t1 and the first direction Y is smaller, on the section perpendicular to the extension line of the first section t1, the angle between the maximum evaporation path formed by the evaporation material ejected from the corresponding nozzle portions 72 and the first side surface C1 is larger, and an overlapping height of the first electrode 50 on the first side surface C1 is also higher.

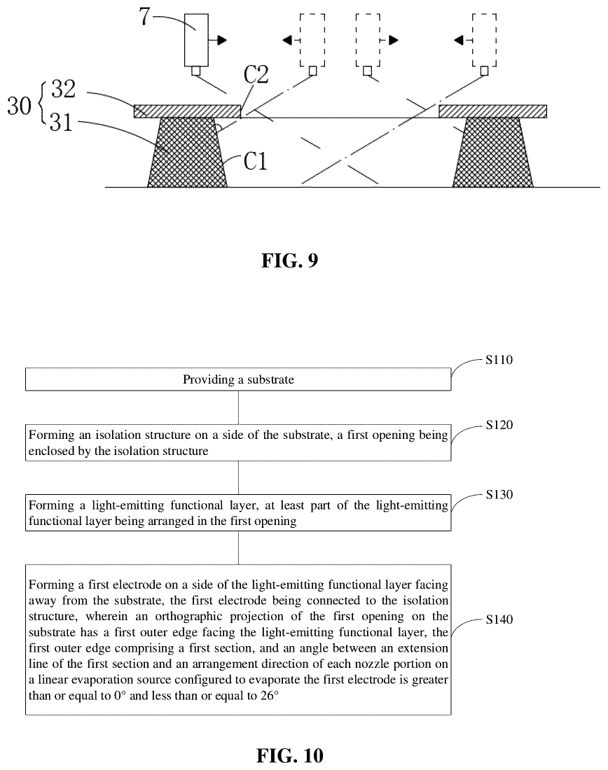

If the angle between the extension line of the first section t1 and the first direction Y is larger, on the section perpendicular to the extension line of the first section t1, the angle between the maximum evaporation path formed by the evaporation material ejected from the corresponding nozzle portions 72 and the first side surface C1 is smaller, and the overlapping height of the first electrode 50 on the first side surface C1 is also lower. Compared with the angle between the maximum evaporation path formed by the evaporation material ejected from the corresponding nozzle portions 72 and the first side surface C1 in the prior art in FIG. 7, the angle between the maximum evaporation path formed by the evaporation material ejected from the corresponding nozzle portions 72 and the first side surface C1 in the display panel provided in this embodiment shown in FIG. 9 is larger, the overlapping height of the first electrode 50 on the first side surface C1 is also higher, which effectively improves the overlapping effect between the first electrode 50 and the isolation structure 30 and improves the display effect of the display panel.

The influence of the angle between the extension line of the first section t1 and the first direction Y on the overlapping height may alternatively be considered by taking a section perpendicular to the arrangement direction of each nozzle portion 72 as an angle of an observation surface. In a direction of the section perpendicular to the arrangement direction of each nozzle portion 72, the angle between the maximum evaporation path formed by the evaporation material ejected from each nozzle portion 72 and the first side surface C1 does not change, but the angle between the extension line of the first section t1 and the first direction Y may affect a distance by which the second part 32 extends outwards relative to the first part 31. If the angle between the extension line of the first section t1 and the first direction Y is larger, in the section perpendicular to the arrangement direction of each nozzle portion 72, the second part 32 extends outwards by a longer distance relative to the first part 31, more of the evaporation material is blocked, and the overlapping height of the first electrode 50 on the first side surface C1 is also lower. On the contrary, if the angle between the extension line of the first section t1 and the first direction Y is larger, in the section perpendicular to the arrangement direction of each nozzle portion 72, the second part 32 extends outwards by a longer distance relative to the first part 31, more of the evaporation material is blocked, and the overlapping height of the first electrode 50 on the first side surface C1 is also lower.

Therefore, in this embodiment, the angle between the extension line of the first section t1 and the first direction Y is limited to a small ranger, that is, greater than or equal to 0° and less than or equal to 26°, to increase the overlapping height of the first electrode 50 on the first side surface C1, which improves the overlapping effect between the first electrode 50 and the isolation structure 30 and improves the display effect of the display panel.

Optionally, the first part 31 includes a first cross section, the first cross section is perpendicular to a plane where the substrate 10 is located, and the first cross section is a regular trapezoid in shape. The first side surface C1 corresponds to a waist of the regular trapezoid, so that the first electrode 50 overlaps the first side surface C1.

In some optional embodiments, a pattern of the orthographic projection of the first opening K on the substrate 10 has a same shape as a pattern of the orthographic projection of the second opening 22 on the substrate 10, which can facilitate the manufacturing and reduce manufacturing costs.

“Has a same shape” may be understood as that the orthographic projection of the second opening 22 on the substrate 10 and the orthographic projection of the first opening K on the substrate 10 are two patterns with equal corresponding angles and proportional corresponding sides. For example, when the pattern of the orthographic projection of the first opening K on the substrate 10 is a rectangle, the pattern of the orthographic projection of the second opening 22 on the substrate 10 may also have a side length smaller than a side length of the pattern of the orthographic projection of the first opening K on the substrate 10 that is a rectangle, and the side lengths of the two rectangles are proportional.

Optionally, the pattern of the orthographic projection of the first opening K on the substrate 10 and the pattern of the orthographic projection of the second opening 22 on the substrate 10 are both a rectangle in shape.

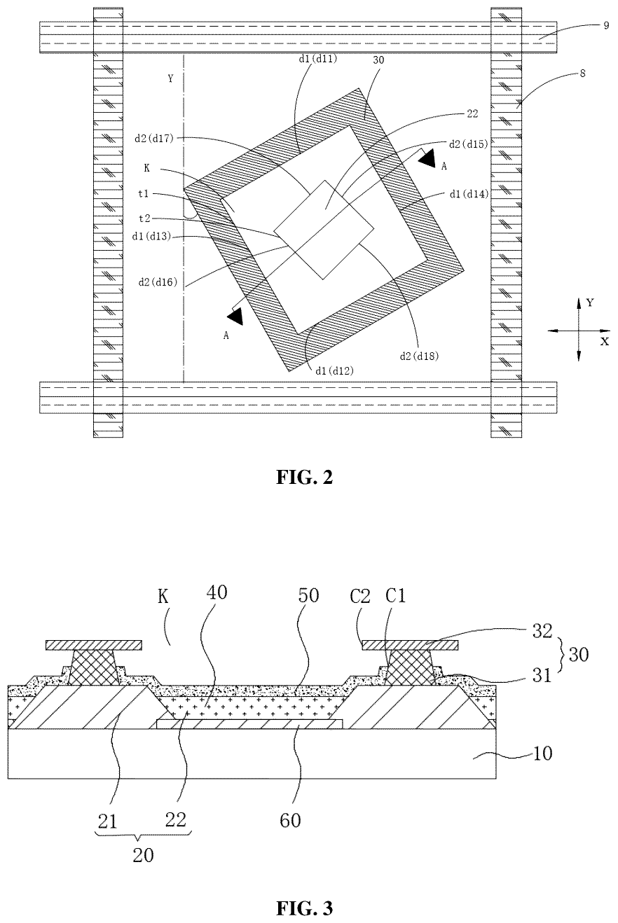

Referring to FIG. 2 or FIG. 4, the first outer edge d1 includes a first edge d11 and a second edge d12 opposite to each other and a third edge d13 and a fourth edge d14 opposite to each other, and the second outer edge d2 includes a fifth edge d15 and a sixth edge d16 opposite to each other and a seventh edge d17 and an eighth edge d18 opposite to each other; and the first section t1 is any one of the first edge d11, the second edge d12, the third edge d13, and the fourth edge d14, the first edge d11 is not parallel to the fifth edge d15 and the seventh edge d17, and the third edge d13 is not parallel to the fifth edge d15 and the seventh edge d17.

Since the pattern of the orthographic projection of the first opening K on the substrate 10 and the pattern of the orthographic projection of the second opening 22 on the substrate 10 are both a rectangle in shape, the first outer edge d1 and the second outer edge d2 respectively include four sides, and two opposite sides are parallel to each other. For example, the first edge d11 and the second edge d12 are parallel to each other, and the third edge d13 and the fourth edge d14 are parallel to each other.

In this embodiment, the first edge d11 is not parallel to the fifth edge d15 and the seventh edge d17, and the third edge d13 is not parallel to the fifth edge d15 and the seventh edge d17. That is, none of the four sides of the first outer edge d1 is parallel to the four sides of the second outer edge d2. That is, compared with a situation in which the sides of the first opening K and the second opening 22 are parallel, the first opening K may be rotated by a certain angle relative to the second opening 22, but a rotation angle is an angle that is not an integral multiple of 90°.

Optionally, angles between an extension line of the first edge d11 and an extension line of the fifth edge d15 as well as an extension line of the seventh edge d17 are both equal to 45°, to ensure that the pattern of the orthographic projection of the first opening K on the substrate 10 may be symmetrically distributed with respect to an axis of symmetry of the pattern of the orthographic projection of the second opening 22 on the substrate 10, thereby ensuring an optical symmetry effect of the display panel.

Referring to FIG. 1 to FIG. 5, an embodiment of the present invention further provides a display panel, including: a substrate 10; an isolation structure 30 arranged on one side of the substrate 10, a first opening K being enclosed by the isolation structure 30; a light-emitting functional layer 40, at least part of the light-emitting functional layer 40 being arranged in the first opening K; and a first electrode 50 arranged on a side of the light-emitting functional layer 40 facing away from the substrate 10, the first electrode 50 being connected to the isolation structure 30. An orthographic projection of the first opening K on the substrate 10 has a first outer edge d1 facing the light-emitting functional layer 40, the first outer edge d1 includes a first section t1, and an angle between an extension line of the first section t1 and an arrangement direction of nozzle portions 72 on a linear evaporation source 7 configured to evaporate the first electrode 50 is greater than or equal to 0° and less than or equal to 26°.

The display panel provided in this embodiment of the present invention includes the substrate 10, the isolation structure 30, the light-emitting functional layer 40, and the first electrode 50. The first opening K is enclosed by the isolation structure 30 to define a setting range of the light-emitting functional layer 40. The orthographic projection of the first opening K on the substrate 10 has the first outer edge d1 facing the light-emitting functional layer 40. The inventor has found through research that when the angle between the extension line of the first section t1 and the arrangement direction of nozzle portions 72 on the linear evaporation source 7 configured to evaporate the first electrode 50 is greater than or equal to 0° and less than or equal to 26° and the first electrode 50 is manufactured, an overlapping height of the first electrode 50 on the isolation structure 30 can be effectively increased, thereby increasing overlapping area between the first electrode 50 and the isolation structure 30, improving overlapping effect between the first electrode 50 and the isolation structure 30, and improving display effect of the display panel.

As shown in FIG. 5, the linear evaporation source 7 is generally a strip in shape. The linear evaporation source 7 is provided with a plurality of nozzle portions 72, and the nozzle portions 72 are arranged along a straight line. An extension direction of the straight line is the arrangement direction of each nozzle portion 72. For example, a body portion 71 and nozzle portions 72 arranged on the body portion 71 along an extension direction of the body portion 71 are included. A plurality of nozzle portions 72 are sequentially arranged on the body portion 71. The arrangement direction of each nozzle portion 72 may affect an evaporation range. The angle between the extension line of the first section t1 and the arrangement direction of each nozzle portion 72 on the linear evaporation source 7 configured to evaporate the first electrode 50 is greater than or equal to 0° and less than or equal to 26°, so as to limit a relative position between the maximum evaporation path formed by the evaporation material ejected from each nozzle portion 72 and the isolation structure 30 and increase the overlapping height of the first electrode 50 on the isolation structure 30, so that the overlapping effect between the first electrode 50 and the isolation structure 30 meets a requirement, improving the display effect of the display panel.

Referring to FIG. 3, in some optional embodiments, the display panel further includes a pixel defining layer 20 arranged between the substrate 10 and the isolation structure 30, the pixel defining layer 20 includes a defining structure 21 and a second opening 22 defined by the defining structure 21, and an orthographic projection of the second opening 22 on the substrate 10 is located within a range of the orthographic projection of the first opening K on the substrate 10.

In this embodiment, an area of the first opening K is greater than or equal to that of the second opening 22, which can reduce an impact of the isolation structure 30 on a light emission viewing angle of the light-emitting functional layer 40.

Optionally, the orthographic projection of the second opening 22 on the substrate 10 has a second outer edged d2, and the first outer edge d1 is not parallel to the second outer edge d2 adjacent thereto.

In the prior art, the second opening 22 and the first opening K generally adopt similar patterns, and opposite edges of the second opening 22 and the first opening K are parallel to each other, that is, there is a fixed matching relationship between the second opening 22 and the first opening K. On the one hand, it is not conducive to targeted adjustment of a light emission effect when the light-emitting functional layer 40 emits light from the first opening K. On the other hand, in order to ensure image quality, the existing second opening 22 generally adopts a shape such as a diamond or a rectangle, and an edge thereof is at an angle of 45° or other angles with the first edge d11 of the display panel, which cannot be parallel or perpendicular. As a result, when the first electrode 50 is formed by evaporation, the angle between the extension line of the first section t1 and the arrangement direction of each nozzle portion 72 on the linear evaporation source 7 configured to evaporate the first electrode 50 cannot satisfy the angle relationship of being greater than or equal to 0° and less than or equal to 26°, which affects a climbing effect of the first electrode 50.

In order to solve the above problem, in this embodiment of the present invention, the matching relationship between the second opening 22 and the first opening K is canceled, so that the first outer edge d1 and the adjacent second outer edge d2 are not parallel, which can adjust, in a targeted manner, the light emission effect when the light-emitting functional layer 40 emits light from the first opening K, and can also improve the overlapping effect between the first electrode 50 and the isolation structure 30 by adjusting the angle between the extension line of the first section t1 and the arrangement direction of each nozzle portion 72 on the linear evaporation source 7 configured to evaporate the first electrode 50.

Optionally, the second outer edge d2 is a polygon in shape, and angles between extension lines of sides of the polygon and the first direction Y are all greater than 26°. Correspondingly, in the prior art, angles between sides of the first outer edge d1 and the first direction Y are all greater than 26°, and the overlapping effect between the first electrode 50 and the isolation structure 30 cannot meet the requirement. Therefore, there is a need to correspondingly adjust the shape of the first outer edge d1 in this embodiment so that the angle between the extension line of the first section t1 and the first direction Y is limited to being greater than or equal to 0° and less than or equal to 26° to increase the overlapping height of the first electrode 50 on the isolation structure 30, and the overlapping effect between the first electrode 50 and the isolation structure 30 meets the requirement, improving the display effect of the display panel.

Optionally, the second outer edge d2 includes a second section t2, and an extension line of the second section t2 is not parallel to the arrangement direction of each nozzle portion 72 on the linear evaporation source 7 configured to evaporate the first electrode 50.

In this embodiment, since the arrangement direction of each nozzle portion 72 on the linear evaporation source 7 configured to evaporate the first electrode 50 is generally parallel to the first direction Y, the extension line of the second section t2 is not parallel to the arrangement direction of each nozzle portion 72 on the linear evaporation source 7 configured to evaporate the first electrode 50, that is, the extension line of the second section t2 is not parallel to the first direction Y, and there is a certain angle between them.

Optionally, the second outer edge d2 includes a second section t2, and an angle between an extension line of the second section t2 and the first direction Y is 45°, that is, an angle between the extension line of the second section t2 and an extension line of the first edge d11 of the display panel is 45°, to ensure a light emission effect of the display panel.

Referring to FIG. 1 to FIG. 3, an embodiment of the present invention further provides a display panel, including: a substrate 10; a data line 8 and a scanning line 9 that are arranged on one side of the substrate 10; an isolation structure 30 arranged on one side of the substrate 10, a first opening K being enclosed by the isolation structure 30; a light-emitting functional layer 40, at least part of the light-emitting functional layer 40 being arranged in the first opening K; and a first electrode 50 arranged on a side of the light-emitting functional layer 40 facing away from the substrate 10, the first electrode 50 being in contact with the isolation structure 30. An orthographic projection of the first opening K on the substrate 10 has a first outer edge d1 facing the light-emitting functional layer 40, the first outer edge d1 includes a first section t1, and an angle between an extension line of the first section t1 and a first direction Y is greater than or equal to 0° and less than or equal to 26°. The first direction Y is an extension direction of either of the data line 8 and the scanning line 9.

The display panel provided in this embodiment of the present invention includes the substrate 10, the isolation structure 30, the light-emitting functional layer 40, and the first electrode 50. The first opening K is enclosed by the isolation structure 30 to define a setting range of the light-emitting functional layer 40. The orthographic projection of the first opening K on the substrate 10 has the first outer edge d1 facing the light-emitting functional layer 40. The first direction Y is the extension direction of either of the data line 8 and the scanning line 9. Since the arrangement direction of each nozzle portion 72 on the linear evaporation source 7 configured to evaporate the first electrode 50 is generally parallel to the first direction Y, the inventor has found through research that when the angle between the extension line of the first section t1 and the first direction Y is greater than or equal to 0° and less than or equal to 26° and the first electrode 50 is manufactured, an overlapping height of the first electrode 50 on the isolation structure 30 can be effectively increased, thereby increasing overlapping area between the first electrode 50 and the isolation structure 30, improving overlapping effect between the first electrode 50 and the isolation structure 30, and improving display effect of the display panel.

Optionally, the extension directions of the data line 8 and the scanning line 9 intersect. For example, the extension directions of the data line 8 and the scanning line 9 are perpendicular, and the first opening K is generally provided in a region defined by the data line 8 and the scanning line 9 to prevent an influence on light emission of the light-emitting functional layer 40.

Optionally, the first direction Y may be defined as the extension direction of the data line 8 according to an actual requirement.

Optionally, the first direction Y is parallel to the arrangement direction of each nozzle portion 72 on the linear evaporation source 7 configured to evaporate the first electrode 50.

The linear evaporation source 7 is generally a strip in shape. The linear evaporation source 7 is provided with a plurality of nozzle portions 72, and the nozzle portions 72 are arranged along a straight line. An extension direction of the straight line is the arrangement direction of each nozzle portion 72. For example, a body portion 71 and nozzle portions 72 arranged on the body portion 71 along an extension direction of the body portion 71 are included. A plurality of nozzle portions 72 are sequentially arranged on the body portion 71. The arrangement direction of each nozzle portion 72 may affect an evaporation range. The first direction Y is parallel to the arrangement direction of each nozzle portion 72 on the linear evaporation source 7 configured to evaporate the first electrode 50. Correspondingly, an angle between the extension line of the first section t1 and the arrangement direction of each nozzle portion 72 on the linear evaporation source 7 configured to evaporate the first electrode 50 is greater than or equal to 0° and less than or equal to 26°, so as to limit a relative position between the maximum evaporation path formed by the evaporation material ejected from each nozzle portion 72 and the isolation structure 30 and increase the overlapping height of the first electrode 50 on the isolation structure 30, so that the overlapping effect between the first electrode 50 and the isolation structure 30 meets a requirement, improving the display effect of the display panel.

Referring to FIG. 3, in some optional embodiments, the display panel further includes a pixel defining layer 20 arranged between the substrate 10 and the isolation structure 30, the pixel defining layer 20 includes a defining structure 21 and a second opening 22 defined by the defining structure 21, and an orthographic projection of the second opening 22 on the substrate 10 is located within a range of the orthographic projection of the first opening K on the substrate 10.

In this embodiment, an area of the first opening K is greater than or equal to that of the second opening 22, which can reduce an impact of the isolation structure 30 on a light emission viewing angle of the light-emitting functional layer 40.

Optionally, the orthographic projection of the second opening 22 on the substrate 10 has a second outer edged d2, and the first outer edge d1 is not parallel to the second outer edge d2 adjacent thereto.

In the prior art, the second opening 22 and the first opening K generally adopt similar patterns, and opposite edges of the second opening 22 and the first opening K are parallel to each other, that is, there is a fixed matching relationship between the second opening 22 and the first opening K. On the one hand, it is not conducive to targeted adjustment of a light emission effect when the light-emitting functional layer 40 emits light from the first opening K. On the other hand, in order to ensure image quality, the existing second opening 22 generally adopts a shape such as a diamond or a rectangle, and an edge thereof is at an angle of 45° or other angles with the first edge d11 of the display panel, which cannot be parallel or perpendicular. As a result, when the first electrode 50 is formed by evaporation, the angle between the extension line of the first section t1 and the arrangement direction of each nozzle portion 72 on the linear evaporation source 7 configured to evaporate the first electrode 50 cannot satisfy the angle relationship of being greater than or equal to 0° and less than or equal to 26°, which affects a climbing effect of the first electrode 50.

In order to solve the above problem, in this embodiment of the present invention, the matching relationship between the second opening 22 and the first opening K is canceled, so that the first outer edge d1 and the adjacent second outer edge d2 are not parallel, which can adjust, in a targeted manner, the light emission effect when the light-emitting functional layer 40 emits light from the first opening K, and can also improve the overlapping effect between the first electrode 50 and the isolation structure 30 by adjusting the angle between the extension line of the first section t1 and the arrangement direction of each nozzle portion 72 on the linear evaporation source 7 configured to evaporate the first electrode 50.

Optionally, the second outer edge d2 is a polygon in shape, and angles between extension lines of sides of the polygon and the first direction Y are all greater than 26°. Correspondingly, in the prior art, angles between sides of the first outer edge d1 and the first direction Y are all greater than 26°, and the overlapping effect between the first electrode 50 and the isolation structure 30 cannot meet the requirement. Therefore, there is a need to correspondingly adjust the shape of the first outer edge d1 in this embodiment so that the angle between the extension line of the first section t1 and the first direction Y is limited to being greater than or equal to 0° and less than or equal to 26° to increase the overlapping height of the first electrode 50 on the isolation structure 30, and the overlapping effect between the first electrode 50 and the isolation structure 30 meets the requirement, improving the display effect of the display panel.

Optionally, the second outer edge d2 includes a second section t2, and an extension line of the second section t2 is not parallel to the arrangement direction of each nozzle portion 72 on the linear evaporation source 7 configured to evaporate the first electrode 50.

In this embodiment, since the arrangement direction of each nozzle portion 72 on the linear evaporation source 7 configured to evaporate the first electrode 50 is generally parallel to the first direction Y, the extension line of the second section t2 is not parallel to the arrangement direction of each nozzle portion 72 on the linear evaporation source 7 configured to evaporate the first electrode 50, that is, the extension line of the second section t2 is not parallel to the first direction Y, and there is a certain angle between them.

Optionally, the second outer edge d2 includes a second section t2, and an angle between an extension line of the second section t2 and the first direction Y is 45°, that is, an angle between the extension line of the second section t2 and an extension line of the first edge d11 of the display panel is 45°, to ensure a light emission effect of the display panel.

An embodiment of the present invention further provides a display panel, including: a substrate 10; an isolation structure 30 arranged on one side of the substrate 10, a first opening K is enclosed by the isolation structure 30; a pixel defining layer 20 arranged on one side of the substrate 10, the pixel defining layer 20 including a defining structure 21 and a plurality of second openings 22 defined by the defining structure 21; and a light-emitting functional layer 40, at least part of the light-emitting functional layer 40 being arranged in the second openings 22. An orthographic projection of the first opening K on the substrate 10 has a first outer edge d1 facing the second opening 22, an orthographic projection of the second opening 22 on the substrate 10 has a second outer edge d2, and the first outer edge d1 is not parallel to the second outer edge d2 adjacent thereto.

The display panel provided in this embodiment of the present invention includes the substrate 10, the pixel defining layer 20, the light-emitting functional layer 40, and the defining structure 21. The light-emitting functional layer 40 may be arranged in the second opening 22 to realize light-emitting display of the display panel. A side of the pixel defining layer 20 facing away from the substrate 10 is provided with the isolation structure 30. In this embodiment of the present invention, by making the first outer edge d1 and the adjacent second outer edge d2 not parallel, a shape and a size of the second opening 22 can be kept unchanged, while a position of the first opening K relative to the second opening 22 is changed. On the one hand, the light emission effect when the light-emitting functional layer 40 emits light from the first opening K can be changed to meet different requirements for the light emission effect. Adjustment of an extension line direction of the first outer edge d1 of the first opening K corresponds to adjustment of an extension direction of an outer edge of the isolation structure 30. On the other hand, when the first electrode 50 is subsequently formed on the side of the light-emitting functional layer 40 away from the substrate 10 through an evaporation process, the overlapping effect between the first electrode 50 and the isolation structure 30 may also be improved by adjusting a relative position between the extension line direction of the first outer edge d1 of the orthographic projection of the first opening K on the substrate 10 and an evaporation direction.

In the prior art, the second opening 22 and the first opening K generally adopt similar patterns, and opposite edges of the second opening 22 and the first opening K are parallel to each other, that is, there is a fixed matching relationship between the second opening 22 and the first opening K. On the one hand, it is not conducive to targeted adjustment of a light emission effect when the light-emitting functional layer 40 emits light from the first opening K. On the other hand, in order to ensure image quality, the existing second opening 22 generally adopts a shape such as a diamond or a rectangle, and an edge thereof is at an angle of 45° or other angles with a bezel of the display panel, which cannot be parallel or perpendicular. As a result, when the first electrode 50 is formed by evaporation, the extension line of the first outer edge d1 of the orthographic projection of the first opening K on the substrate 10 and the moving direction of the linear evaporation source 7 for evaporation are at an angle of 45° or other angles, which cannot be perpendicular, affecting a climbing effect of the first electrode 50.

In order to solve the above problem, in this embodiment of the present invention, the second opening 22 and the first opening K are not in a matching relationship, so that the first outer edge d1 and the adjacent second outer edge d2 are not parallel, which can adjust, in a targeted manner, the light emission effect when the light-emitting functional layer 40 emits light from the first opening K, and can also improve the overlapping effect between the first electrode 50 after entering the first opening K and the isolation structure 30 by adjusting a relative position between an extension line direction of the first outer edge d1 of the orthographic projection of the first opening K on the substrate 10 and an evaporation direction. In some optional embodiments, the display panel further includes a first electrode 50, the first electrode 50 is located on a side of the light-emitting functional layer 40 facing away from the substrate 10, and the first electrode 50 is connected to the isolation structure 30. The first outer edge d1 includes a first section t1, and an angle between an extension line of the first section t1 and the arrangement direction of each nozzle portion 72 on the linear evaporation source 7 configured to evaporate the first electrode 50 is greater than or equal to 0° and less than or equal to 26°.

The linear evaporation source 7 is generally a strip in shape. The linear evaporation source 7 is provided with a plurality of nozzle portions 72, and the nozzle portions 72 are arranged along a straight line. An extension direction of the straight line is the arrangement direction of each nozzle portion 72. For example, a body portion 71 and nozzle portions 72 arranged on the body portion 71 along an extension direction of the body portion 71 are included. A plurality of nozzle portions 72 are sequentially arranged on the body portion 71. The arrangement direction of each nozzle portion 72 may affect an evaporation range. The angle between the extension line of the first section t1 and the arrangement direction of each nozzle portion 72 on the linear evaporation source 7 configured to evaporate the first electrode 50 is greater than or equal to 0° and less than or equal to 26°, so as to limit a relative position between the maximum evaporation path formed by the evaporation material ejected from each nozzle portion 72 and the isolation structure 30 and increase the overlapping height of the first electrode 50 on the isolation structure 30, so that the overlapping effect between the first electrode 50 and the isolation structure 30 meets a requirement, improving the display effect of the display panel.

Optionally, the second outer edge d2 is a polygon in shape, and angles between extension lines of sides of the polygon and the first direction Y are all greater than 26°. Correspondingly, in the prior art, angles between sides of the first outer edge d1 and the first direction Y are all greater than 26°, and the overlapping effect between the first electrode 50 and the isolation structure 30 cannot meet the requirement. Therefore, there is a need to correspondingly adjust the shape of the first outer edge d1 in this embodiment so that the angle between the extension line of the first section t1 and the first direction Y is limited to being greater than or equal to 0° and less than or equal to 26° to increase the overlapping height of the first electrode 50 on the isolation structure 30, and the overlapping effect between the first electrode 50 and the isolation structure 30 meets the requirement, improving the display effect of the display panel.

Optionally, the second outer edge d2 includes a second section t2, and an extension line of the second section t2 is not parallel to the arrangement direction of each nozzle portion 72 on the linear evaporation source 7 configured to evaporate the first electrode 50.

In this embodiment, since the arrangement direction of each nozzle portion 72 on the linear evaporation source 7 configured to evaporate the first electrode 50 is generally parallel to the first direction Y, the extension line of the second section t2 is not parallel to the arrangement direction of each nozzle portion 72 on the linear evaporation source 7 configured to evaporate the first electrode 50, that is, the extension line of the second section t2 is not parallel to the first direction Y, and there is a certain angle between them.

Optionally, the second outer edge d2 includes a second section t2, and an angle between an extension line of the second section t2 and the first direction Y is 45°, that is, an angle between the extension line of the second section t2 and an extension line of the first edge d11 of the display panel is 45°, to ensure a light emission effect of the display panel.

Referring to FIG. 3, in some optional embodiments, a pattern of the orthographic projection of the first opening K on the substrate 10 has a same shape as a pattern of the orthographic projection of the second opening 22 on the substrate 10, which can facilitate the manufacturing and reduce manufacturing costs.

“Has a same shape” may be understood as that the orthographic projection of the second opening 22 on the substrate 10 and the orthographic projection of the first opening K on the substrate 10 are two patterns with equal corresponding angles and proportional corresponding sides. For example, when the pattern of the orthographic projection of the first opening K on the substrate 10 is a rectangle, the pattern of the orthographic projection of the second opening 22 on the substrate 10 may also have a side length smaller than a side length of the pattern of the orthographic projection of the first opening K on the substrate 10 that is a rectangle, and the side lengths of the two rectangles are proportional.

Optionally, the pattern of the orthographic projection of the first opening K on the substrate 10 and the pattern of the orthographic projection of the second opening 22 on the substrate 10 are both a rectangle in shape.

Referring to FIG. 2 or FIG. 4, the first outer edge d1 includes a first edge d11 and a second edge d12 opposite to each other and a third edge d13 and a fourth edge d14 opposite to each other, and the second outer edge d2 includes a fifth edge d15 and a sixth edge d16 opposite to each other and a seventh edge d17 and an eighth edge d18 opposite to each other; and the first section t1 is any one of the first edge d11, the second edge d12, the third edge d13, and the fourth edge d14, the first edge d11 is not parallel to the fifth edge d15 and the seventh edge d17, and the third edge d13 is not parallel to the fifth edge d15 and the seventh edge d17.

Since the pattern of the orthographic projection of the first opening K on the substrate 10 and the pattern of the orthographic projection of the second opening 22 on the substrate 10 are both a rectangle in shape, the first outer edge d1 and the second outer edge d2 respectively include four sides, and two opposite sides are parallel to each other. For example, the first edge d11 and the second edge d12 are parallel to each other, and the third edge d13 and the fourth edge d14 are parallel to each other.

In this embodiment, the first edge d11 is not parallel to the fifth edge d15 and the seventh edge d17, and the third edge d13 is not parallel to the fifth edge d15 and the seventh edge d17. That is, none of the four sides of the first outer edge d1 is parallel to the four sides of the second outer edge d2. That is, compared with a situation in which the sides of the first opening K and the second opening 22 are parallel, the first opening K may be rotated by a certain angle relative to the second opening 22, but a rotation angle is an angle that is not an integral multiple of 90°.

Optionally, angles between an extension line of the first edge d11 and an extension line of the fifth edge d15 as well as an extension line of the seventh edge d17 are both equal to 45°, to ensure that the pattern of the orthographic projection of the first opening K on the substrate 10 may be symmetrically distributed with respect to an axis of symmetry of the pattern of the orthographic projection of the second opening 22 on the substrate 10, thereby ensuring an optical symmetry effect of the display panel.

Referring to FIG. 10, an embodiment of the present invention further provides a method for manufacturing a display panel, including the following steps.

In S110, a substrate 10 is provided, as shown in FIG. 11.

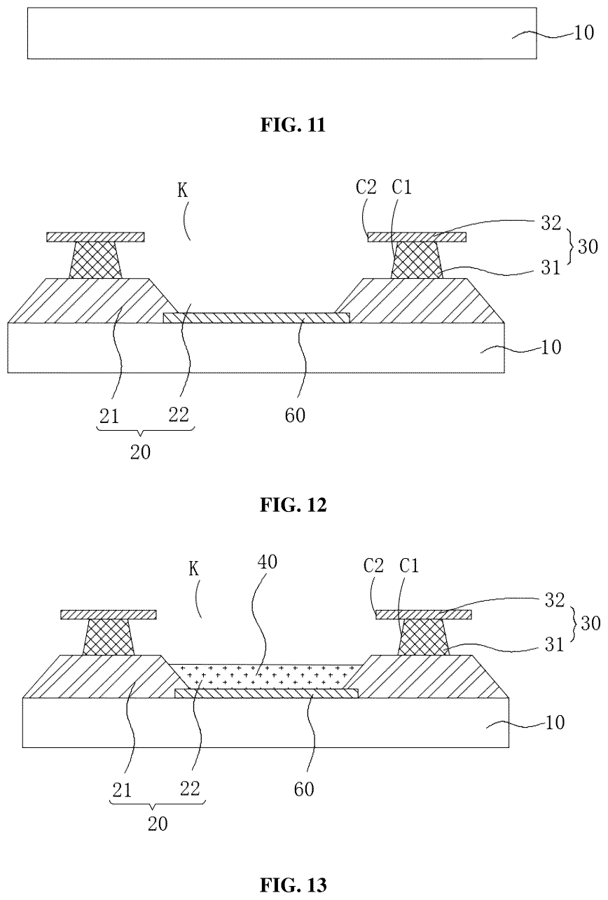

In S120, an isolation structure 30 is formed on one side of the substrate 10, and a first opening K is enclosed by the isolation structure 30, as shown in FIG. 12.

In S130, a light-emitting functional layer 40 is formed, and at least part of the light-emitting functional layer 40 is arranged in the first opening K, as shown in FIG. 13.

In S140, a first electrode 50 is formed on a side of the light-emitting functional layer 40 facing away from the substrate 10, the first electrode 50 is connected to the isolation structure 30, an orthographic projection of the first opening K on the substrate 10 has a first outer edge d1 facing the light-emitting functional layer 40, the first outer edge d1 includes a first section t1, and an angle between an extension line of the first section t1 and an arrangement direction of nozzle portions 72 on a linear evaporation source 7 configured to evaporate the first electrode 50 is greater than or equal to 0° and less than or equal to 26°, as shown in FIG. 2 and FIG. 3.

In the method for manufacturing the display panel provided in this embodiment of the present invention, the first opening K is enclosed by the isolation structure 30 to define a setting range of the light-emitting functional layer 40. The orthographic projection of the first opening K on the substrate 10 has the first outer edge d1 facing the light-emitting functional layer 40. The inventor has found through research that when the angle between the extension line of the first section t1 and the arrangement direction of each nozzle portion 72 on the linear evaporation source 7 configured to evaporate the first electrode 50 is greater than or equal to 0° and less than or equal to 26° and the first electrode 50 is manufactured, an overlapping height of the first electrode 50 on the isolation structure 30 can be effectively increased, thereby increasing overlapping area between the first electrode 50 and the isolation structure 30, improving overlapping effect between the first electrode 50 and the isolation structure 30, and improving display effect of the display panel.

In step S110, the substrate 10 may be specifically formed through a process such as coating, curing, or film forming. The substrate 10 may be a hard substrate, such as a glass substrate, which may alternatively be a flexible substrate and be made of polyimide, polystyrene, polyethylene terephthalate, polyparaxylene, polyethersulfone, or polyethylene naphthalate. The substrate 10 is mainly configured to support devices arranged thereon.

In step S120, the isolation structure 30 may specifically be formed through a process such as evaporation or sputtering.

In step S130, film layers of the light-emitting functional layer 40 such as an electron injection layer, an electron transport layer, a hole blocking layer, a light-emitting material layer, an electron blocking layer, a hole transport layer, and a hole injection layer may be formed through an evaporation process.

In step S140, the linear evaporation source 7 is generally a strip in shape. The linear evaporation source 7 is provided with a plurality of nozzle portions 72, and the nozzle portions 72 are arranged along a straight line. An extension direction of the straight line is the arrangement direction of each nozzle portion 72. For example, a body portion 71 and nozzle portions 72 arranged on the body portion 71 along an extension direction of the body portion 71 are included. A plurality of nozzle portions 72 are sequentially arranged on the body portion 71. The arrangement direction of each nozzle portion 72 may affect an evaporation range.

The angle between the extension line of the first section t1 and the arrangement direction of each nozzle portion 72 on the linear evaporation source 7 configured to evaporate the first electrode 50 is greater than or equal to 0° and less than or equal to 26°, so as to limit a relative position between the maximum evaporation path formed by the evaporation material ejected from each nozzle portion 72 and the isolation structure 30 and increase the overlapping height of the first electrode 50 on the isolation structure 30, so that the overlapping effect between the first electrode 50 and the isolation structure 30 meets a requirement, improving the display effect of the display panel.

In some optional embodiments, between the step of providing a substrate 10 and the step of forming an isolation structure 30 on one side of the substrate 10, the method further includes: forming a pixel defining layer 20 on one side of the substrate 10, the pixel defining layer 20 including a defining structure 21 and a second opening 22 defined by the defining structure 21, and an orthographic projection of the second opening 22 on the substrate 10 having a second outer edge d2; and in the step of forming an isolation structure 30 on one side of the substrate 10, the first outer edge d1 being not parallel to the second outer edge d2 adjacent thereto.

In the prior art, the second opening 22 and the first opening K generally adopt similar patterns, and opposite edges of the second opening 22 and the first opening K are parallel to each other, that is, there is a fixed matching relationship between the second opening 22 and the first opening K. On the one hand, it is not conducive to targeted adjustment of a light emission effect when the light-emitting functional layer 40 emits light from the first opening K. On the other hand, in order to ensure image quality, the existing second opening 22 generally adopts a shape such as a diamond or a rectangle, and an edge thereof is at an angle of 45° or other angles with a bezel of the display panel, which cannot be parallel or perpendicular. As a result, when the first electrode 50 is formed by evaporation, the angle between the extension line of the first section t1 and the arrangement direction of each nozzle portion 72 on the linear evaporation source 7 configured to evaporate the first electrode 50 cannot satisfy the angle relationship of being greater than or equal to 0° and less than or equal to 26°, which affects a climbing effect of the first electrode 50.

In order to solve the above problem, in this embodiment of the present invention, the matching relationship between the second opening 22 and the first opening K is canceled, so that the first outer edge d1 and the adjacent second outer edge d2 are not parallel, which can adjust, in a targeted manner, the light emission effect when the light-emitting functional layer 40 emits light from the first opening K, and can also improve the overlapping effect between the first electrode 50 and the isolation structure 30 by adjusting the angle between the extension line of the first section t1 and the arrangement direction of each nozzle portion 72 on the linear evaporation source 7 configured to evaporate the first electrode 50.

Optionally, the second outer edge d2 is a polygon in shape, and angles between extension lines of sides of the polygon and the first direction Y are all greater than 26°. Correspondingly, in the prior art, angles between sides of the first outer edge d1 and the arrangement direction of each nozzle portion 72 on the linear evaporation source 7 configured to evaporate the first electrode 50 are all greater than 26°, and the overlapping effect between the first electrode 50 and the isolation structure 30 cannot meet the requirement. Therefore, there is a need to correspondingly adjust the shape of the first outer edge d1 in this embodiment so that the angle between the extension line of the first section t1 and the arrangement direction of each nozzle portion 72 on the linear evaporation source 7 configured to evaporate the first electrode 50 is greater than or equal to 0° and less than or equal to 26° to increase the overlapping height of the first electrode 50 on the isolation structure 30, and the overlapping effect between the first electrode 50 and the isolation structure 30 meets the requirement, improving the display effect of the display panel.

Optionally, in the step of forming a first electrode on a side of the light-emitting functional layer facing away from the substrate, the arrangement direction of each nozzle portion 72 on the linear evaporation source 7 configured to evaporate the first electrode 50 is not parallel to an extension line of a second section t2.

In this embodiment, since the arrangement direction of each nozzle portion 72 on the linear evaporation source 7 configured to evaporate the first electrode 50 is generally parallel to the extension direction of the first sub-edge B1 of the display panel, that is, the first direction Y, the extension line of the second section t2 is not parallel to the arrangement direction of each nozzle portion 72 on the linear evaporation source 7 configured to evaporate the first electrode 50, that is, the extension line of the second section t2 is not parallel to the first direction Y, and there is a certain angle between them.

Optionally, the second outer edge d2 includes a second section t2, and an angle between an extension line of the second section t2 and the first direction Y is 45°, that is, an angle between the extension line of the second section t2 and an extension line of the first edge d11 of the display panel is 45°, to ensure a light emission effect of the display panel.

Optionally, the arrangement direction of each nozzle portion 72 on the linear evaporation source 7 is parallel to the moving direction of the linear evaporation source 7. The inventor has found through research that the moving direction of the linear evaporation source 7 configured to evaporate the first electrode 50 may also affect the overlapping height of the first electrode 50 on the isolation structure 30, when the arrangement direction of each nozzle portion 72 on the linear evaporation source 7 configured to evaporate the first electrode 50 is perpendicular to the moving direction of the linear evaporation source 7 configured to evaporate the first electrode 50 and the angle between the extension line of the first section t1 and the arrangement direction of each nozzle portion 72 on the linear evaporation source 7 configured to evaporate the first electrode 50 is greater than or equal to 0° and less than or equal to 26°, the overlapping height of the first electrode 50 on the isolation structure 30 meets a requirement, which can realize stable overlapping between the first electrode 50 and the isolation structure 30, improving the display effect of the display panel.

The display panel provided in the embodiments of the present application may be applied to mobile phones, or may be any electronic product having a display function, including, but not limited to, the following categories: televisions, laptop computers, desktop displays, tablet computers, digital cameras, mobile phones, smart bracelets, smart glasses, on-board displays, medical devices, industrial control devices and touch interactive terminals, which is not specially limited in the embodiments of the present application.

The above are merely specific implementations of the present application. It may be clearly understood by those skilled in the art that, for the purpose of convenient and brief description, specific operating processes of the foregoing system, module, and unit may be obtained with reference to the corresponding processes in the foregoing method embodiments, and details are not described herein again. It should be understood that the protection scope of the present application is not limited thereto. Those skilled in the art may readily figure out various modifications or replacements within the technical scope disclosed in the present application, all of which may fall within the protection scope of the present application.

It should also be noted that the exemplary embodiments mentioned in the present application describe some methods or systems based on a series of steps or apparatuses. However, the present application is not limited to the order of the above steps. In other words, the steps may be performed in the order mentioned in the embodiments, or may be performed in an order different from the order in the embodiments, or a number of steps may be performed simultaneously.

What is claimed is:

1. A display panel, the display panel having a first sub-edge extending along a first direction, the display panel comprising:
a substrate;
an isolation structure arranged on a side of the substrate, a first opening being enclosed by the isolation structure;
a light-emitting functional layer, at least part of the light-emitting functional layer being arranged in the first opening; and
a first electrode arranged on a side of the light-emitting functional layer facing away from the substrate, the first electrode being connected to the isolation structure;
wherein an orthographic projection of the first opening on the substrate has a first outer edge facing the light-emitting functional layer, the first outer edge comprises a first section, and an angle between an extension line of the first section and the first direction is greater than or equal to 0° and less than or equal to 26°.

2. The display panel of claim 1, wherein the display panel comprises a data line and a scanning line, one of the data line and the scanning line extends along the first direction, and the other extends along a second direction, and the first direction intersects the second direction.

3. The display panel of claim 1, wherein the first outer edge is a polygon in shape and comprises a plurality of sides with different lengths, and the first section is the longest side of the plurality of sides with different lengths.

4. The display panel of claim 1, further comprising a pixel defining layer arranged between the substrate and the isolation structure, the pixel defining layer comprising a defining structure and a second opening defined by the defining structure, and an orthographic projection of the second opening on the substrate being located within a range of the orthographic projection of the first opening on the substrate;
wherein the orthographic projection of the second opening on the substrate has a second outer edge, and the first outer edge is not parallel to the second outer edge adjacent thereto.

5. The display panel of claim 4, wherein the second outer edge is a polygon in shape, and an angle between an extension line of each side of the polygon and the first direction is greater than 26°.

6. The display panel of claim 4, wherein the second outer edge comprises a second section, and an angle between an extension line of the second section and the first direction is 45°.

7. The display panel of claim 4, wherein the orthographic projection of the second opening on the substrate has at least one axis of symmetry, and the orthographic projection of the first opening on the substrate is symmetrically arranged with respect to the at least one axis of symmetry.

8. The display panel of claim 1, wherein the isolation structure comprises a first part and a second part sequentially arranged along a direction away from the substrate, and an orthographic projection of the first part on the substrate is located within an orthographic projection of the second part on the substrate.

9. The display panel of claim 8, wherein the first part comprises a first side surface facing the first opening and overlapping with the first electrode, the second part comprises a second side surface facing the first opening, and an edge of the orthographic projection of the first part on the substrate is parallel to an edge of the orthographic projection of the second part on the substrate,
wherein an edge of the orthographic projection of the first part on the substrate coincides with the first outer edge; or an edge of the orthographic projection of the second part on the substrate coincides with the first outer edge, and
wherein the first part comprises a first cross section, the first cross section is perpendicular to a plane where the substrate is located, and the first cross section is a regular trapezoid in shape.

10. The display panel of claim 4, wherein a pattern of the orthographic projection of the first opening on the substrate has a same shape as a pattern of the orthographic projection of the second opening on the substrate.

11. The display panel of claim 4, wherein the first outer edge comprises a first edge and a second edge opposite to each other and a third edge and a fourth edge opposite to each other, and the second outer edge comprises a fifth edge and a sixth edge opposite to each other and a seventh edge and an eighth edge opposite to each other; and the first section is any one of the first edge, the second edge, the third edge, and the fourth edge, the first edge is not parallel to both of the fifth edge and the seventh edge, and the third edge is not parallel to both of the fifth edge and the seventh edge.

12. The display panel of claim 11, wherein an angle between an extension line of the first edge and an extension line of the fifth edge and an angle between an extension line of the first edge and an extension line of the seventh edge are both equal to 45°.

13. A display panel, comprising:
a substrate;
a data line and a scanning line that are arranged on a side of the substrate;
an isolation structure arranged on a side of the substrate, a first opening being enclosed by the isolation structure;
a light-emitting functional layer, at least part of the light-emitting functional layer being arranged in the first opening; and
a first electrode arranged on a side of the light-emitting functional layer facing away from the substrate, the first electrode being in contact with the isolation structure;
wherein an orthographic projection of the first opening on the substrate has a first outer edge facing the light-emitting functional layer, the first outer edge comprising a first section, and an angle between an extension line of the first section and a first direction is greater than or equal to 0° and less than or equal to 26°, wherein the first direction is an extension direction of any one of the data line and the scanning line.

14. The display panel of claim 13, wherein the first direction is the extension direction of the data line.

15. The display panel of claim 13, further comprising a pixel defining layer arranged between the substrate and the isolation structure, the pixel defining layer comprising a defining structure and a second opening defined by the defining structure, and an orthographic projection of the second opening on the substrate being located within a range of the orthographic projection of the first opening on the substrate;
wherein the orthographic projection of the second opening on the substrate has a second outer edge, and the first outer edge is not parallel to the second outer edge adjacent thereto.

16. The display panel of claim 15, wherein the second outer edge is a polygon in shape, and an angle between an extension line of each side of the polygon and the first direction is greater than 26°.

17. The display panel of claim 15, wherein the second outer edge comprises a second section, and an angle between an extension line of the second section and the first direction is 45°.

18. A method for manufacturing a display panel, comprising the following steps:
providing a substrate;
forming an isolation structure on a side of the substrate, a first opening being enclosed by the isolation structure;
forming a light-emitting functional layer, at least part of the light-emitting functional layer being arranged in the first opening; and
forming a first electrode on a side of the light-emitting functional layer facing away from the substrate, the first electrode being connected to the isolation structure, wherein an orthographic projection of the first opening on the substrate has a first outer edge facing the light-emitting functional layer, the first outer edge comprising a first section, and an angle between an extension line of the first section and an arrangement direction of each nozzle portion on a linear evaporation source configured to evaporate the first electrode is greater than or equal to 0° and less than or equal to 26°.

19. The method of claim 18, between the step of providing a substrate and the step of forming an isolation structure on a side of the substrate, further comprising: forming a pixel defining layer on a side of the substrate, the pixel defining layer comprising a defining structure and a second opening defined by the defining structure, and an orthographic projection of the second opening on the substrate having a second outer edge; and
in the step of forming an isolation structure on a side of the substrate, the first outer edge being not parallel to the second outer edge adjacent thereto.

20. The method of claim 19, wherein in the step of forming a first electrode on a side of the light-emitting functional layer facing away from the substrate,
the arrangement direction of each nozzle portion on the linear evaporation source is not parallel to an extension line of a second section of the second outer edge.

21. The method of claim 19, wherein the second outer edge is a polygon in shape, and an angle between an extension line of each side of the polygon and the arrangement direction of each nozzle portion on the linear evaporation source is greater than 26°.

22. The method of claim 20, wherein an angle between the extension line of the second section and the arrangement direction of each nozzle portion on the linear evaporation source is 45°.

23. The method of claim 20, wherein the arrangement direction of each nozzle portion on the linear evaporation source is perpendicular to a moving direction of the linear evaporation source.
